(19) United States
(12) Patent Application Publication
(10) Pub. No.: US 2022/0383901 A1
(43) Pub. Date: Dec. 1, 2022

(54) SPUTTERING TARGET FOR HEAT-ASSISTED MAGNETIC RECORDING MEDIUM

(71) Applicants: TANAKA KIKINZOKU KOGYO K.K., Tokyo (JP); Tohoku University, Miyagi (JP)

(72) Inventors: Kim Kong Tham, Ibaraki (JP); Ryousuke Kushibiki, Ibaraki (JP); Shin Saito, Miyagi (JP); Takashi Saito, Miyagi (JP)

(21) Appl. No.: 17/773,526

(22) PCT Filed: Oct. 27, 2020
(86) PCT No.: PCT/JP2020/040215

§ 371 Date: Apr. 29, 2022

(30) Foreign Application Priority Data
Nov. 1, 2019 (JP) 2019-199915

(51) Int. Cl. G11B 5/851; G11B 5/02; G11B 5/65

(52) U.S. Cl. CPC G11B 5/851; G11B 5/02; G11B 5/65; C23C 14/34

(57) ABSTRACT

Provided is a sputtering target to be used for forming a granular magnetic thin film in which FePt magnetic grains are isolated by an oxide and which constitutes a heat-assisted magnetic recording medium having enhanced uniaxial magnetic anisotropy, thermal stability, and SNR (signal-to-noise ratio).

The sputtering target for a heat-assisted magnetic recording medium contains an FePt alloy and a nonmagnetic material as main components, where the nonmagnetic material is an oxide having a melting point of 800° C. or higher and 1100° C. or lower.

### TECHNICAL FIELD

The present invention relates to a sputtering target for a heat-assisted magnetic recording medium and particularly relates to a sputtering target for a heat-assisted magnetic recording medium, containing an Fe—Pt alloy and a nonmagnetic material as main components.

### BACKGROUND ART

In a magnetic disk of a hard disk drive, information signals are recorded in tiny bits of a magnetic recording medium. To further increase the recording density of the magnetic recording medium, it is necessary to shrink the size of each bit that retains a piece of recorded information while enhancing a signal-to-noise ratio, which is an indicator of information quality. To enhance a signal-to-noise ratio, it is essential to increase a signal or to reduce a noise.

As a magnetic recording medium for recording information signals, a magnetic thin film having a CoPt alloy-oxide granular structure is used today (see Non Patent Literature (NPL) 1, for example). The granular structure is formed from columnar CoPt alloy grains and the surrounding oxide grain boundaries.

To increase the recording density of such a magnetic recording medium, it is necessary to smoothen transition regions between recording bits and thereby to reduce noise. To smoothen transition regions between recording bits, it is required to reduce the size of the CoPt alloy grains contained in the magnetic thin film.

Meanwhile, when the size of magnetic grains is reduced, the intensity of a recorded signal that can be retained by one magnetic grain decreases. To reduce the size of magnetic grains while ensuring the intensity of recorded signals, it is necessary to reduce the distance between grain centers.

Moreover, when the size of the CoPt alloy grains in the magnetic recording medium is reduced further, there arise in some cases so-called thermal fluctuations, in which recorded signals are lost due to the thermal stability impaired by superparamagnetism. Such thermal fluctuations are a major obstacle to a higher recording density of a magnetic disk.

To overcome this obstacle, it is necessary to increase the magnetic energy in each CoPt alloy grain so as to predominate over the thermal energy. The magnetic energy of each CoPt alloy grain is determined by v×Ku, which is the product of the volume v and the magnetocrystalline anisotropy constant Kᵤ of the CoPt alloy grain. Accordingly, to increase the magnetic energy of the CoPt alloy grain, it is essential to increase the magnetocrystalline anisotropy constant Kᵤ of the CoPt alloy grain (see NPL 2, for example).

Further, to grow columnar CoPt alloy grains having a large Ku, it is required to realize the phase separation between CoPt alloy grains and a grain boundary material. When intergranular interactions between CoPt alloy grains increase due to insufficient phase separation between CoPt alloy grains and a grain boundary material, a magnetic thin film having a CoPt alloy-oxide granular structure exhibits a low coercivity H_{c}. Consequently, thermal fluctuations tend to arise due to impaired thermal stability. Accordingly, it is also important to reduce intergranular interactions between CoPt alloy grains.

It may be possible to reduce the size of magnetic grains as well as the distance between the centers of the magnetic grains by reducing the size of grains in a Ru underlayer (underlayer provided for orientation control of a magnetic recording medium).

However, it is difficult to reduce the size of grains in a Ru underlayer while maintaining the crystal orientation (see NPL 3, for example). For this reason, the grain size of a Ru underlayer for current magnetic recording media is about 7 nm to 8 nm with little change from the size when longitudinal magnetic recording media were switched to perpendicular magnetic recording media.

Meanwhile, further reduction in size of magnetic grains has also been studied by improving a magnetic recording layer rather than a Ru underlayer. Specifically, in a CoPt alloy-oxide magnetic thin film, reduction in size of magnetic grains has been investigated by increasing the amount of an oxide to be added while reducing the volume ratio of the magnetic grains (see NPL 4, for example). By this technique, the size of the magnetic grains was reduced successfully. However, since the widths of grain boundaries increase in this technique as the amount of an oxide to be added increases, it is impossible to reduce the distance between the centers of the magnetic grains.

Furthermore, in addition to a single oxide used for conventional CoPt alloy-oxide magnetic thin films, addition of a second oxide has been investigated (see NPL 5, for example). However, when a plurality of oxide materials are to be added, guidelines for selecting such materials have not yet been clarified and oxides used as grain boundary materials for CoPt alloy grains remain under study even today. Meanwhile, the present inventors found the effectiveness of incorporating a low-melting oxide and a high-melting oxide (specifically, incorporating B2O3 having a melting point as low as 450° C. and a high-melting oxide having a melting point higher than a CoPt alloy (about 1450° C.)) for realizing the reduction in size of magnetic grains as well as distance between the centers of the magnetic grains in a magnetic thin film and thus have proposed a sputtering target for magnetic recording, comprising a CoPt alloy and oxides including B2O3 and a high-melting oxide (Patent Literature (PTL) 1).

Meanwhile, an FePt alloy having L1₀ structure but not CoPt alloys has been drawing attention as a material for ultrahigh density recording media, and a granular magnetic thin film in which FePt magnetic grains are isolated by C (carbon) has been proposed as a magnetic recording medium for the next-generation hard disks that adopt a heat-assisted magnetic recording mode (PTL 2). However, C (carbon) is a material hard to sinter and hence is extremely difficult to obtain a dense sintered body. Consequently, there is a problem of generating a large amount of particles during sputtering. Further, as described hereinafter, the experiments conducted by the present inventors revealed that the saturation magnetization (Ms^{grain}) is low when C (carbon) is used as a grain boundary material for FePt magnetic grains. A low saturation magnetization is not preferable since thermal stability decreases.

### CITATION LIST

### Patent Literature

PTL 1: WO 2018/083951

PTL 2: Japanese Patent No. 5946922

### Non Patent Literature

NPL 1: T. Oikawa et al., IEEE Transactions on Magnetics, September 2002, Vol. 38, No. 5, pp. 1976-1978

NPL 2: S. N. Piramanayagam, Journal of Applied Physics, 2007, 102, 011301

NPL 3: S. N. Piramanayagam et al., Applied Physics Letters, 2006, 89, 162504

NPL 4: Y. Inaba et al., IEEE Transactions on Magnetics, July 2004, Vol. 40, No. 4, pp. 2486-2488

NPL 5: I. Tamai et al., IEEE Transactions on Magnetics, November 2008, Vol. 44, No. 11, pp. 3492-3495

### SUMMARY OF INVENTION

### Technical Problem

For a further high capacity, an object of the present invention is to provide a sputtering target to be used for forming a granular magnetic thin film in which FePt magnetic grains are isolated by an oxide and which constitutes a heat-assisted magnetic recording medium having enhanced uniaxial magnetic anisotropy, thermal stability, and SNR (signal-to-noise ratio).

### Solution to Problem

The present inventors investigated the saturation magnetization (Ms^{grain}) and magnetocrystalline anisotropy constant [Kᵤ^{grain} (Kᵤ for FePt magnetic grains excluding an oxide)] as an indicator of thermal stability for various oxides as grain boundary materials that isolate FePt magnetic grains. Consequently, the present inventors found possible to obtain a heat-assisted magnetic recording medium having both a high saturation magnetization (Mₛ^{grain}) and a large magnetocrystalline anisotropy constant (Kᵤ^{grain}) by using an oxide having a melting point within a particular range; and found effective to use a sputtering target containing, as a nonmagnetic material, such an oxide having a melting point within a particular range for forming the heat-assisted magnetic recording medium, thereby completing the present invention.

The present invention provides a sputtering target for a heat-assisted magnetic recording medium (hereinafter, also simply referred to as “sputtering target” or “target” in some cases), comprising an FePt alloy, a nonmagnetic material, and incidental impurities, where the nonmagnetic material is an oxide having a melting point of 800° C. or higher and 1100° C. or lower.

The sputtering target of the present invention contains an FePt alloy as a main component. The FePt alloy constitutes magnetic grains (tiny magnets) in the granular structure of a magnetic thin film, which is to be formed by sputtering, of a heat-assisted magnetic recording medium.

Fe is a ferromagnetic metal element and plays a central role in the formation of magnetic grains (tiny magnets) in the granular structure of a magnetic thin film of a heat-assisted magnetic recording medium. From a viewpoint of increasing the magnetocrystalline anisotropy constant Kᵤ of FePt alloy grains (magnetic grains) in a magnetic thin film to be obtained by sputtering as well as a viewpoint of maintaining the magnetism of FePt alloy grains (magnetic grains) in the obtained magnetic thin film, the Fe content ratio in the sputtering target of the present invention is set to preferably 40 mol % or more and 60 mol % or less and more preferably 45 mol % or more and 55 mol % or less based on all the metal components.

Pt acts to reduce the magnetic moment of an alloy with Fe through alloying within a predetermined compositional range and thus plays a role in adjusting the strength of the magnetism of magnetic grains. From a viewpoint of increasing the magnetocrystalline anisotropy constant Kᵤ of FePt alloy grains (magnetic grains) in a magnetic thin film, which is to be obtained by sputtering, of a heat-assisted magnetic recording medium as well as a viewpoint of adjusting the magnetism of FePt alloy grains (magnetic grains) in the magnetic thin film to be obtained, the Pt content ratio in the sputtering target of the present invention is set to preferably 40 mol % or more and 60 mol % or less and more preferably 45 mol % or more and 55 mol % or less based on all the metal components.

Moreover, the sputtering target of the present invention may further contain, in addition to Fe and Pt, one or more additional elements selected from Ag, Au, and Cu as metal components. These metal elements are added to lower the temperature of heat treatment that is conducted to have Llo structure predominantly in a sputtered thin film. The amounts of these metal elements to be added are not particularly limited unless the characteristics as a magnetic thin film of a heat-assisted magnetic recording medium are damaged. For example, the content ratio of an additional metal element in the sputtering target of the present invention is preferably 0 mol % or more and 20 mol % or less and more preferably 0 mol % or more and 10 mol % or less based on all the metal components.

Hereinafter, an alloy consisting of Fe and Pt is referred to as “FePt alloy,” and an alloy containing, in addition to Fe and Pt, one or more elements selected from Ag, Au, and Cu is referred to as “FePt-based alloy.”

The nonmagnetic material contained in the sputtering target of the present invention is an oxide having a melting point of 800° C. or higher and 1100° C. or lower. In a magnetic film obtained through deposition by sputtering a target that contains an oxide having a melting point of 800° C. or higher and 1100° C. or lower, it is possible to dispose the oxide as a grain boundary material for FePt magnetic grains. A heat-assisted magnetic recording medium having the resulting magnetic film can realize a saturation magnetization (Mₛ^{grain}) of about 950 emu/cm³ or more and a magnetocrystalline anisotropy constant (Kᵤ^{grain}) of 2.5×10′ erg/cm³ or more. As described in detail hereinafter, it was found as shown in FIGS. 2 and 3 that the saturation magnetization (Mₛ^{grain}) is higher at a lower melting point of an oxide used as a grain boundary material for FePt magnetic grains and that both the saturation magnetization (Mₛ^{grain}) and magnet ocrystalline anisotropy constant (Kᵤ^{grain}) cannot be increased together when an oxide having a melting point lower than 800° C. is used as a grain boundary material due to its low magnetocrystalline anisotropy constant (Kᵤ^{grain}). For these reasons, the sputtering target of the present invention was determined to contain an oxide having a melting point of 800° C. or higher and 1100° C. or lower. By using such a sputtering target, the oxide is allowed to act as a grain boundary material in a heat-assisted magnetic recording medium. Particularly preferable examples of the oxide having a melting point of 800° C. or higher and 1100° C. or lower include one or more oxides selected from SnO (melting point of 1080° C.), PbO (melting point of 886° C.), and Bi2O3 (melting point of 817° C.).

The content of a nonmagnetic material in the sputtering target of the present invention is preferably 25 vol % or more and 40 vol % or less, more preferably 27 vol % or more and 36 vol % or less, and further preferably 29 vol % or more and 32 vol % or less. By setting the content of a nonmagnetic material within the above-mentioned ranges, it is possible in a magnetic layer, which is to be formed by using the sputtering target of the present invention, of a magnetic recording medium to reliably separate FePt magnetic grains and to readily isolate the magnetic grains, thereby increasing the recording density.

The microstructure of the sputtering target of the present invention is not particularly limited but is preferably a microstructure in which the metal phase and the oxide phase are finely dispersed each other. Such a microstructure is less likely to cause trouble, such as nodules or particles, during sputtering.

The sputtering target of the present invention can be produced as follows, for example.

A molten FePt alloy is prepared from the metal components each weighed to have a predetermined composition. The molten alloy was gas-atomized to yield an FePt alloy atomized powder. The prepared FePt alloy atomized powder is classified into a predetermined particle size or less (106 μm or less, for example).

The prepared FePt alloy atomized powder is added with an oxide powder (SnO, PbO, and/or Bi₂O₃) having a melting point of 800° C. or higher and 1100° C. or lower and, as necessary, an additional metal element powder (Ag, Au, and/or Cu, for example) and mixed/dispersed in a ball mill to yield a mixed powder for pressure sintering. Through mixing/dispersing in a ball mill of the FePt alloy atomized powder, the oxide powder, and another metal element powder used as necessary, it is possible to prepare a mixed powder for pressure sintering in which the FePt alloy atomized powder, the oxide powder, and another metal element powder used as necessary are mutually and finely dispersed.

Alternatively, an FePt-based alloy atomized powder containing an additional metal element together with Fe and Pt may be added with an oxide powder (SnO, PbO, and/or Bi2O3) having a melting point of 800° C. or higher and 1100° C. or lower and mixed/dispersed in a ball mill to yield a mixed powder for pressure sintering.

The prepared mixed powder for pressure sintering is formed to produce a sputtering target through pressure sintering by a vacuum hot press process, for example. Since the mixed powder for pressure sintering has been mixed/dispersed in a ball mill, the FePt alloy atomized powder, the oxide powder, and another metal element powder used as necessary are mutually and finely dispersed, or alternatively, the FePt-based alloy atomized powder and the oxide powder are finely dispersed each other. For this reason, when sputtering is performed using a sputtering target obtained by the present production method, trouble, such as generation of particles or nodules, is less likely to arise. Here, the process by which the mixed powder for pressure sintering is pressure-sintered is not particularly limited, and a process other than a vacuum hot press process, such as an HIP process, may be employed.

To prepare a mixed powder for pressure sintering, each metal element powder may be used without being limited to alloy atomized powders. In this case, a mixed powder for pressure sintering can be prepared by mixing/dispersing Fe metal powder, Pt metal powder, the oxide powder, and another metal element powder used as necessary in a ball mill.

### Advantageous Effects of Invention

The sputtering target for a heat-assisted magnetic recording medium of the present invention can form a granular magnetic thin film of a high recording density magnetic recording medium that exhibits enhanced uniaxial magnetic anisotropy, thermal stability, and SNR.

### BRIEF DESCRIPTION OF DRAWINGS

FIG. 1 shows magnetization curves of FePt granular magnetic recording media having an FePt-30 vol % X (X is a nonmagnetic material) magnetic film.

FIG. 2 is a graph showing the relationship between the magnetocrystalline anisotropy (Kᵤ^{grain}) and the melting point of each nonmagnetic material for the FePt granular magnetic recording media having an FePt-30 vol % X (X is a nonmagnetic material) magnetic film.

FIG. 3 is a graph showing the relationship between the saturation magnetization (Mₛ^{grain}) and the melting point of each nonmagnetic material for the FePt granular magnetic recording media having an FePt-30 vol % X (X is a nonmagnetic material) magnetic film.

FIG. 4 is a graph showing the relationship between the coercivity (Hₑ) and the melting point of each nonmagnetic material for the FePt granular magnetic recording media having an FePt-30 vol % X (X is a nonmagnetic material) magnetic film.

FIG. 5 shows X-ray diffraction profiles in which the crystal orientation of perpendicular and parallel components of some heat-assisted FePt granular magnetic recording media is measured by X-ray diffraction.

FIG. 6 is a graph showing the relationship between the degree of order (Sᵢₙ) and the melting point of each nonmagnetic material for the FePt granular magnetic recording media having an FePt-30 vol % X (X is a nonmagnetic material) magnetic film.

FIG. 7 is a graph showing the relationship between the grain diameter (GD) and the melting point of each nonmagnetic material for the FePt granular magnetic recording media having an FePt-30 vol % X (X is a nonmagnetic material) magnetic film.

FIG. 8 is a graph showing the relationship between the degree of order (Sᵢₙ) and the grain diameter (GD) of each nonmagnetic material for the FePt granular magnetic recording media having an FePt-30 vol % X (X is a nonmagnetic material) magnetic film.

FIG. 9 is a graph showing the relationship between the coercivity (Hₑ) and the grain diameter (GD) of each nonmagnetic material for the FePt granular magnetic recording media having an FePt-30 vol % X (X is a nonmagnetic material) magnetic film.

FIG. 10 is a graph showing the relationship between the coercivity (Hₑ) and the degree of order (Sᵢₙ) of each nonmagnetic material for the FePt granular magnetic recording media having an FePt-30 vol % X (X is a nonmagnetic material) magnetic film.

FIG. 11 is a graph showing the relationship between the magnetocrystalline anisotropy (Kᵤ^{grain}) and the nonmagnetic material content for FePt granular magnetic recording media having an FePt-SnO magnetic film.

FIG. 12 is a graph showing the relationship between the saturation magnetization (Mₛ^{grain}) and the nonmagnetic material content for the FePt granular magnetic recording media having an FePt-SnO magnetic film.

FIG. 13 is a graph showing the relationship between the coercivity (Hₑ) and the nonmagnetic material content for the FePt granular magnetic recording media having an FePt-SnO magnetic film.

### EXAMPLES

Hereinafter, the present invention will be described specifically, but the present invention is by no means limited thereto.

### Example 1

Targets of FePt-30 vol % X (X is a nonmagnetic material) were produced through mixing with 30 vol % of the respective nonmagnetic materials shown in Table 1.

First, a 50Fe-50Pt alloy atomized powder was prepared. Specifically, the 50Fe-50Pt alloy atomized powder was prepared by weighing each metal to satisfy the composition of 50 at % of Fe and 50 at % of Pt and by heating both the metals to 1,500° C. or higher to form a molten alloy, followed by gas atomization.

The prepared 50Fe-50Pt alloy atomized powder was classified through a 150 mesh sieve to obtain a 50Fe-50Pt alloy atomized powder having a particle size of 106 μm or less.

To satisfy the composition of (50Fe-50Pt)-30 vol % X (X is each nonmagnetic material shown in Table 1), each nonmagnetic material powder as X shown in Table 1 was added to the classified 50Fe-50Pt alloy atomized powder and mixed/dispersed in a ball mill to yield 16 mixed powders for pressure sintering, each containing a different nonmagnetic material.

Subsequently, each prepared mixed powder for pressure sintering was hot-pressed under vacuum conditions to yield a sintered body. For example, a stepped target of (50Fe-50Pt)-30 vol % SnO having a diameter of 153.0×1.0 mm (upper level) +a diameter of 161.0×4.0 mm (lower level) was produced using SnO as a nonmagnetic material X by hot pressing under vacuum conditions of a sintering temperature of 960° C., a sintering pressure of 24.5 MPa, a sintering time of 60 minutes, and an atmosphere of 5×10′ Pa or lower. The produced target had a relative density of 96.5%. For other nonmagnetic materials, sintered bodies were prepared under the conditions shown in Table 2 to produce the respective targets.

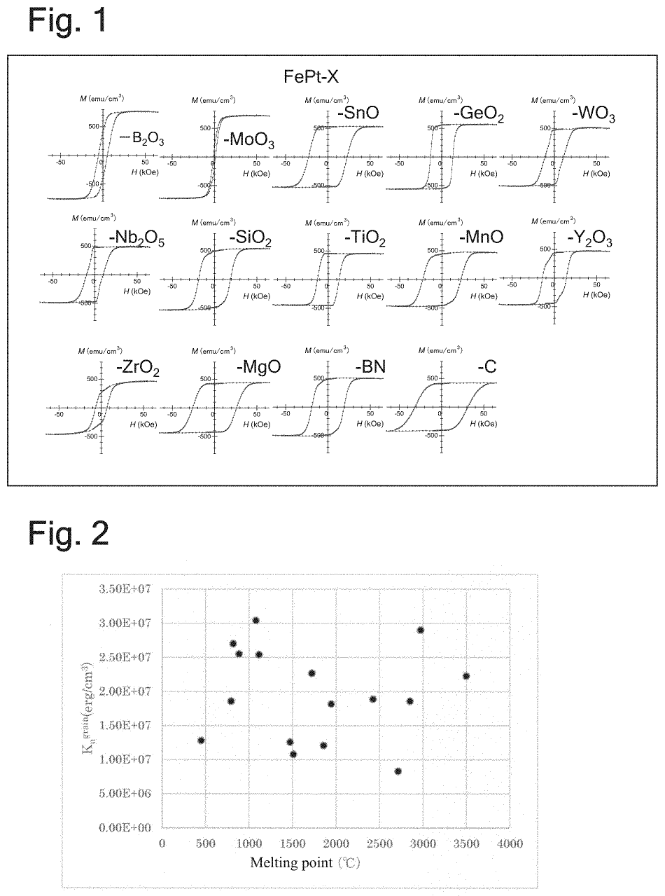

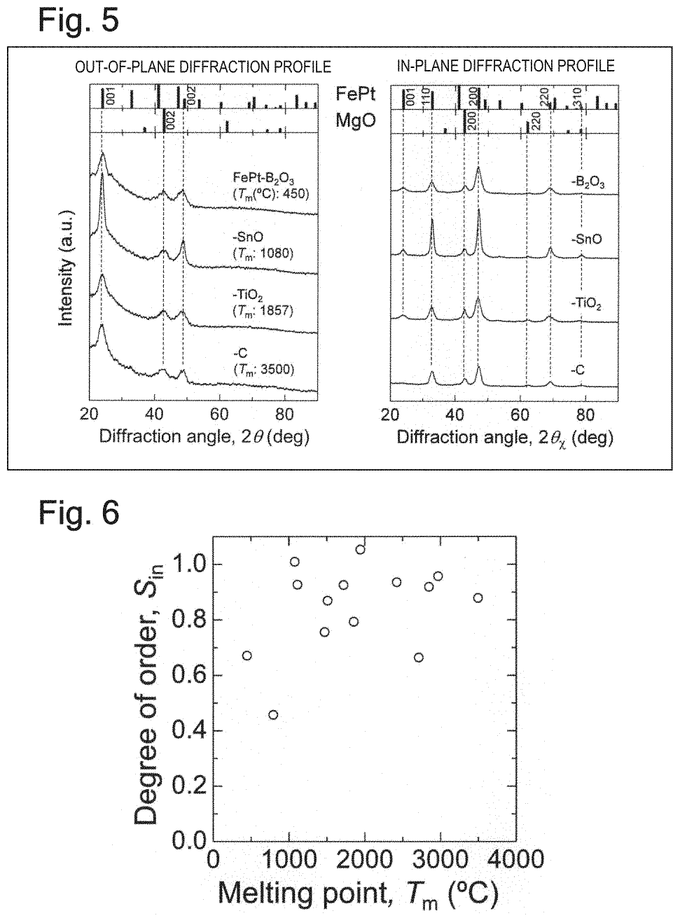

Sputtering was performed using the produced target in a DC sputtering apparatus (from Canon Anelva Corporation) to form a magnetic thin film of (50Fe-50Pt)-30 vol % X on a glass substrate, thereby preparing a sample for magnetic characteristics measurement and a sample for structure observation. Specifically, each heat-assisted FePt granular magnetic recording medium was obtained by depositing a CoW seed layer at a thickness of 80 nm on a glass substrate by DC sputtering (1.5 kW, 0.6 Pa), depositing a MgO underlayer at a thickness of 5 nm on the CoW seed layer by RF magnetron sputtering (0.5 kW, 4.0 Pa), depositing an FePt-30 vol % X (X is each nonmagnetic material shown in Table 1) magnetic film at a thickness of 10 nm on the MgO underlayer by DC sputtering (0.1 kW, 8.0 Pa, Ar gas), and depositing a C surface protective layer at a thickness of 7 nm on the magnetic film by DC sputtering (0.3 kW, 0.6 Pa). The magnetic characteristics (magnetocrystalline anisotropy and saturation magnetization) were measured using a SQUID-VSM (max. 7 T) and a PPMS torque magnetometer (max. 9 T). The measured results are shown in Table 1, and the magnetization curve is shown in FIG. 1. Moreover, the relationships between the melting point of each nonmagnetic material and the respective magnetocrystalline anisotropy (Kᵤ^{grain}) saturation magnetization (Mₛ^{grain}), ₐnd coercivity (H_{c}) for heat-assisted FePt granular magnetic recording media are plotted and shown in FIGS. 2, 3, and 4. Further, FIG. 5 shows the crystal orientation of perpendicular and parallel components of some heat-assisted FePt granular magnetic recording media measured by X-ray diffraction.

Furthermore, the degree of order (Sᵢₙ) of each heat-assisted FePt granular magnetic recording medium was calculated according to formula (1) from the integral intensities of FePt(110) and FePt(220) diffraction peaks in the measured results of the crystal orientation of perpendicular components in FIG. 5. FIG. 6 is a graph on which the relationship between the degree of order (Sᵢₙ) and the melting point of each nonmagnetic material is plotted. The degree of order Sᵢₙ represents the extent of a structure in which Fe and Pt atoms are repeatedly stacked in the film thickness direction. When Fe and Pt atoms are repeatedly stacked completely without defects, Sᵢₙ is 1.0 (theoretical value). Meanwhile, when Fe and Pt atoms are never repeatedly stacked completely, Sᵢₙ is 0.

$$[ Formula 1 ]$$

$${S}_{i n} = \sqrt{\frac{{( I \text{?} / I \text{?} )}_{measured}}{{( I \text{?} / I \text{?} )}_{calculated}}} \qquad ( 1 )$$

$$\text{?} \text{indicates text missing or illegible when filed}$$

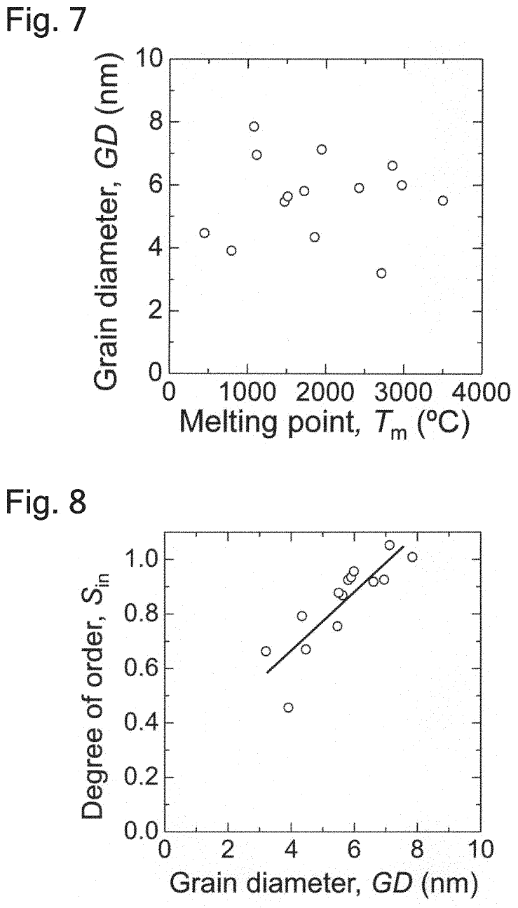

Further, the grain diameter (GD) of each heat-assisted FePt granular magnetic recording medium was assessed according to formula (2) by using the FePt(200) diffraction peak in the in-plane diffraction profile of FIG. 5. FIG. 7 is a graph on which the relationship between the grain diameter (GD) and the melting point of each nonmagnetic material is plotted.

$$[ Formula 2 ]$$

$$GD = \frac{0.9 λ}{βcos θχ} \qquad ( 2 )$$

Here, λ is the wavelength of 0.1542 nm for the radiation source of the X-ray diffractometer, β is a full width at half maximum of the FePt(200) diffraction peak, and θ_{χ} is a diffraction angle of the FePt(200) diffraction peak.

Further, the correlation between the degree of order and the grain diameter, the correlation between the coercivity (H_{c}) and the grain diameter, and the correlation between the coercivity (H_{c}) and the degree of order are collectively shown in FIGS. 8, 9, and 10, respectively.

TABLE 1
Measured Results

| Non- | Melting | | | H_{c} |
|---|---|---|---|---|
| magnetic | point | Mₛ^{grain} | Kᵤ^{grain} | (coercivity) |
| material | ° C. | emu/cm³ | erg/cm³ | kOe |
| B₂O₃ | 450 | 1079 | 1.28E+07 | 3.50 |
| MoO₃ | 795 | 1059 | 1.86E+07 | 0.26 |
| SnO | 1080 | 1014 | 3.04E+07 | 29.00 |
| PbO | 886 | 955 | 2.55E+07 | 24.00 |
| Bi₂O₃ | 817 | 975 | 2.70E+07 | 26.00 |
| GeO₂ | 1115 | 914 | 2.54E+07 | 19.50 |
| WO₃ | 1473 | 944 | 1.26E+07 | 8.50 |
| Nb₂O₅ | 1512 | 881 | 1.08E+07 | 15.63 |
| SiO₂ | 1723 | 836 | 2.27E+07 | 19.00 |
| TiO₂ | 1857 | 837 | 1.21E+07 | 9.50 |
| MnO | 1945 | 823 | 1.82E+07 | 26.68 |
| Y₂O₃ | 2425 | 796 | 1.89E+07 | 6.50 |
| Zr₂O | 2715 | 824 | 0.83E+07 | 6.50 |
| MgO | 2852 | 791 | 1.86E+07 | 26.08 |
| BN | 2973 | 764 | 2.94E+07 | 21.50 |
| C | 3500 | 710 | 2.23E+07 | 29.25 |

TABLE 2
Sintering Conditions for Nonmagnetic
Materials and Relative Density of Targets

| | Sintering | | | | |
|---|---|---|---|---|---|
| Non- | temper- | Sintering | Sintering | Atmos- | Relative |
| magnetic | ature | pressure | time | phere | density |
| material | ° C. | MPa | min | Pa | % |
| B₂O₃ | 800 | 30.6 | 60 | 5 × 10⁻² | 102.5 |
| MoO₃ | 980 | 24.5 | 60 | 5 × 10⁻² | 101.4 |
| SnO | 960 | 24.5 | 60 | 5 × 10⁻² | 96.5 |
| PbO | 960 | 24.5 | 60 | 5 × 10⁻² | 96.8 |
| Bi₂O3 | 960 | 24.5 | 60 | 5 × 10⁻² | 97.2 |
| GeO₂ | 770 | 24.5 | 60 | 5 × 10⁻² | 102.0 |
| WO₃ | 1040 | 24.5 | 60 | 5 × 10⁻² | 101.2 |
| Nb₂O₅ | 1070 | 24.5 | 60 | 5 × 10⁻² | 102.4 |
| SiO₂ | 990 | 30.6 | 60 | 5 × 10⁻² | 95.7 |
| TiO₂ | 1020 | 24.5 | 60 | 5 × 10⁻² | 96.8 |
| MnO | 950 | 24.5 | 60 | 5 × 10⁻² | 98.8 |
| Y₂O₃ | 1200 | 24.5 | 60 | 5 × 10⁻² | 96.5 |
| Zr₂O | 1000 | 24.5 | 60 | 5 × 10⁻² | 97.1 |
| MgO | 940 | 24.5 | 60 | 5 × 10⁻² | 95.7 |
| BN | 900 | 65.7 | 60 | 5 × 10⁻² | 90.2 |
| C | 900 | 30.6 | 60 | 5 × 10⁻² | 91.2 |

FIG. 1 reveals that the hysteresis of magnetic recording media is dependent on grain boundary materials (nonmagnetic materials of sputtering targets) and that satisfactory results are obtained when SnO (melting point of 1080° C.), MnO (melting point of 1945° C.), MgO (melting point of 2852° C.), or C (melting point of 3500° C.) is used as a grain boundary material. Moreover, it is found from Table 1 that the coercivity is also high when SnO (melting point of 1080° C.), MnO (melting point of 1945° C.), or C (melting point of 3500° C.) is used.

FIG. 2 reveals that the magnetocrystalline anisotropy (Kᵤ^{grain}) of _{magne}ti_{c} recording media is dependent on grain boundary materials (nonmagnetic materials of sputtering targets) and that a large magnetocrystalline anisotropy of 2.5×10⁷ erg/cm³ or more is exhibited when SnO (melting point of 1080° C.), PbO (melting point of 886° C.), Bi2O3 (melting point of 817° C.), GeO2 (melting point of 1115° C.), or BN (melting point of 2973° C.) is used as a grain boundary material.

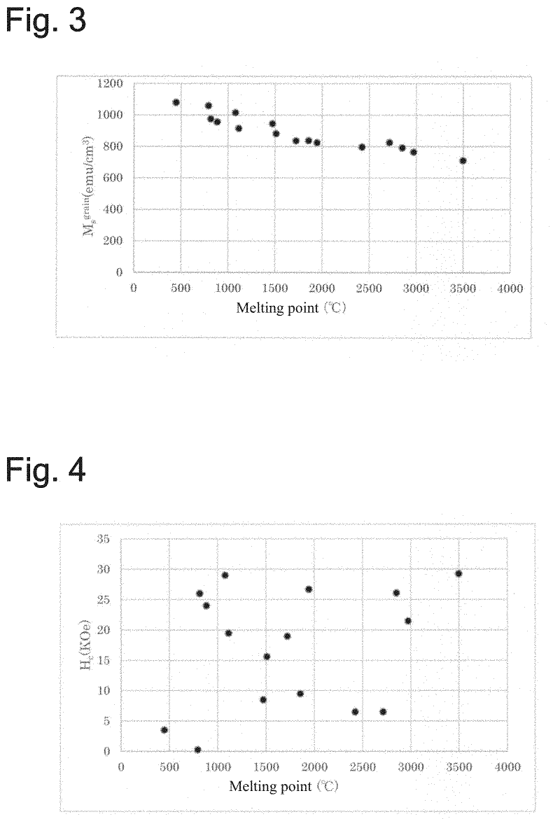

FIG. 3 reveals that the saturation magnetization (ngraⁱn) of _{magne}ti_{c recor}din_{g} media is dependent on grain boundary materials (nonmagnetic materials of sputtering targets); the high correlation particularly with the melting point of each grain boundary material is observed; the saturation magnetization is higher at a lower melting point; a saturation magnetization of 950 emu/cm³ or more is exhibited when SnO (melting point of 1080° C.), PbO (melting point of 886° C.), or Bi2O3 (melting point of 817° C.) is used as a grain boundary material; and a saturation magnetization of 1000 emu/cm³ or more is exhibited particularly when SnO (melting point of 1080° C.) is used.

In FIG. 4, no correlation is observed between the coercivity (H_{c}) of magnetic recording media and the melting point of each grain boundary material (each nonmagnetic material of sputtering targets). However, it is found that high coercivities of 24 kOe, 26 kOe, and about 30 kOe are exhibited when PbO (melting point of 886° C.), Bi2O3 (melting point of 817° C.), and SnO (melting point of 1080° C.) are respectively used as grain boundary materials.

FIG. 5 reveals in the out-of-plane diffraction profile of some magnetic recording media that the FePt(001) diffraction peak is more intense when SnO (melting point of 1080° C.) is used as a grain boundary material than when another grain boundary material of C (melting point of 3500° C.), B2O3 (melting point of 450° C.), or TiO2 (melting point of 1857° C.) is used. Moreover, in the in-plane diffraction profile of the magnetic recording media, it is found further clearly due to the reduced overall noise that the FePt(110) diffraction peak is more intense when SnO (melting point of 1080° C.) is used as a grain boundary material than when another grain boundary material of C (melting point of 3500° C.), B2O3 (melting point of 450° C.), or TiO2 (melting point of 1857° C.) is used. Accordingly, it is confirmed that the perpendicular direction is an easy axis direction when SnO is used.

FIG. 6 reveals that the degree of order of magnetic recording media weakly correlates with the melting point of each grain boundary material (each nonmagnetic material of sputtering targets) and that a high degree of order close to 1.0 is exhibited when SnO (melting point of 1080° C.) is used as a grain boundary material.

FIG. 7 reveals that the grain diameter of magnetic recording media weakly correlates with the melting point of each grain boundary material (each nonmagnetic material of sputtering targets) and that a large grain diameter of about 8 nm is exhibited when SnO (melting point of 1080° C.) is used as a grain boundary material.

FIG. 8 reveals that the degree of order of magnetic recording media satisfactorily correlates with the grain diameter and that the degree of order is higher at a larger grain diameter.

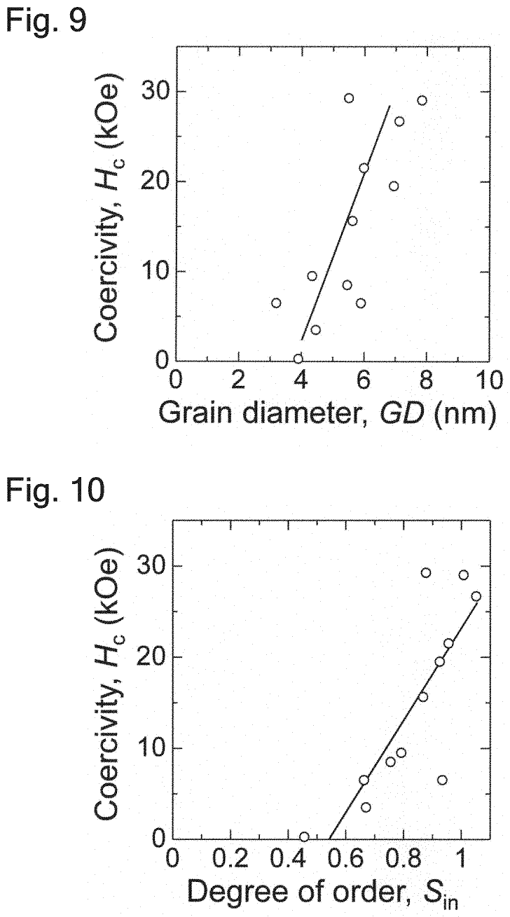

FIG. 9 reveals that the coercivity (Hₑ) of magnetic recording media satisfactorily correlates with the grain diameter and that the coercivity is higher at a larger grain diameter.

FIG. 10 reveals that the coercivity (Hₑ) of magnetic recording media satisfactorily correlates with the degree of order and that the coercivity is higher at a higher degree of order.

From the foregoing results, it was found that a grain boundary material that can satisfy all of satisfactory hysteresis, high coercivity, high magnetocrystalline anisotropy (Kᵤ^{grain}), hi_{g}h ₛₐturation magnetization (Mₛ^{grain}), an easy axis direction in the perpendicular direction, high degree of order, and satisfactory columnar growth of grains is an oxide having a melting point of 800° C. or higher and 1100° C. or lower, as typified by SnO. Although only SnO, PbO, or Bi2O3, which is an oxide having a melting point of 800° C. or higher and 1100° C. or lower, was used as a grain boundary material in the present working example, it is considered that similar effects are exhibited also when another oxide having a melting point within the same range is used as a grain boundary material.

### Example 2

In the same manner as Example 1 except for changing the 50Fe-50Pt alloy atomized powder into a 47.5Fe-47.5Pt-5Y alloy atomized powder (Y is Au, Ag, or Cu) containing 5 at % of Au, Ag, or Cu as shown in Table 3, each stepped target of FePtY-30 vol % SnO (Y is Au, Ag, or Cu) having a diameter of 153.0×1.0 mm (upper level) +a diameter of 161.0×4.0 mm (lower level) was prepared through hot pressing under vacuum conditions of a sintering temperature of 960° C., a sintering pressure of 24.5 MPa, a sintering time of 60 minutes, and an atmosphere of 5×10⁻² Pa or lower; and each heat-assisted FePt granular magnetic recording medium was produced as well. The magnetic characteristics (magnetocrystalline anisotropy and saturation magnetization) were measured, and the measured results are shown in Table 3.

TABLE 3
Measured Results

| | Melting | | | |
|---|---|---|---|---|
| | point of | | | |
| | nonmagnetic | Mₛ^{grain} | | H_{c} |
| Target | material | emu/ | Kᵤ^{grain} | (coercivity) |
| composition | ° C. | cm³ | erg/cm³ | kOe |
| (50Fe50Pt)-30 | 1080 | 1014 | 3.04E+07 | 29 |
| vol % SnO | | | | |
| (47.5Fe47.5Pt5Au)- | 1080 | 953 | 3.20E+07 | 31 |
| 30 vol % SnO | | | | |
| (47.5Fe47.5Pt5Ag)- | 1080 | 955 | 3.50E+07 | 33 |
| 30 vol % SnO | | | | |
| (47.5Fe47.5Pt5Cu)- | 1080 | 960 | 3.80E+07 | 36 |
| 30 vol % SnO | | | | |

The addition of Au, Ag, or Cu tends to reduce saturation magnetization (Mₛ^{grain}) and to increase magnetocrystalline anisotropy (Kᵤ^{grain}) and coercivity (Hₑ) although the variation ranges are small. Accordingly, it is confirmed that a heat-assisted magnetic recording medium even produced using an FePt-based alloy sputtering target containing Au, Ag, or Cu exhibits magnetic characteristics similar to those of a recording medium produced using a 50Fe-50Pt alloy sputtering target. Meanwhile, it was confirmed that an FePt-based alloy sputtering target containing Au, Ag, or Cu can increase the relative density as shown that the sputtering targets of (50Fe50Pt)-30 vol % SnO, (47.5Fe47.5Pt5Au)-30 vol % SnO, (47.5Fe47.5Pt5Ag)-30 vol % SnO, and (47.5Fe47.5Pt5Cu)-30 vol % SnO had relative densities of 96.5%, 98.2%, 97.8%, and 97.3%, respectively.

### Example 3

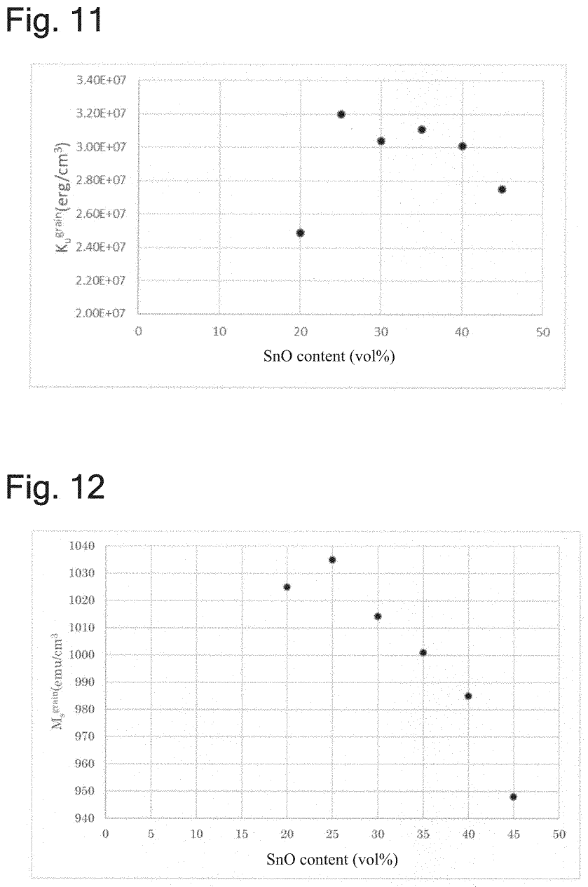

In the same manner as Example 1 except for changing as shown in Table 4 the content of SnO nonmagnetic material, each stepped target of FePt-SnO having a diameter of 153.0×1.0 mm (upper level) +a diameter of 161.0×4.0 mm (lower level) was prepared through hot pressing under vacuum conditions of a sintering temperature of 960° C., a sintering pressure of 24.5 MPa, a sintering time of 60 minutes, and an atmosphere of 5×10⁻² Pa or lower; and each heat-assisted FePt granular magnetic recording medium was produced as well. The magnetic characteristics (magnetocrystalline anisotropy and saturation magnetization) were measured, and the measured results are shown in Table 4. The relationships between the SnO content and the respective magnetocrystalline anisotropy (Kᵤ^{grain}), saturation magnetization (Mₛ^{grain}), and coercivity (H_{c}) for heat-assisted FePt granular magnetic recording media are plotted and shown in FIGS. 11, 12, and 13.

TABLE 4
Measured Results

| | Melting | | | |
|---|---|---|---|---|
| | point of | | | |
| | nonmagnetic | Mₛ^{grain} | | H_{c} |
| Target | material | emu/ | Kᵤ^{grain} | (coercivity) |
| composition | ° C. | cm³ | erg/cm³ | kOe |
| (50Fe50Pt)-20 | 1080 | 1025 | 2.49E+07 | 21 |
| vol % SnO | | | | |
| (50Fe50Pt)-25 | 1080 | 1035 | 3.20E+07 | 28 |
| vol % SnO | | | | |
| (50Fe50Pt)-30 | 1080 | 1014 | 3.04E+07 | 29 |
| vol % SnO | | | | |
| (50Fe50Pt)-35 | 1080 | 1001 | 3.11E+07 | 29 |
| vol % SnO | | | | |
| (50Fe50Pt)-40 | 1080 | 985 | 3.01E+07 | 27 |
| vol % SnO | | | | |
| (50Fe50Pt)-45 | 1080 | 948 | 2.75E+07 | 22 |
| vol % SnO | | | | |

FIGS. 11 and 12 reveal that the saturation magnetization (Mₛ^{grain}) and magnetocrystalline anisotropy (Kᵤ^{grain}) are maxima when the content of SnO nonmagnetic material is 25 vol % and decrease as the content increases over 25 vol %; a high saturation magnetization (Mₛ^{grain}) of 950 emu/cm³ or more is exhibited when the content of SnO nonmagnetic material is 20 vol % or more and 45 vol % or less and a high saturation magnetization exceeding 980 emu/cm³ is exhibited particularly when the content is 20 vol % or more and 40 vol % or less; and a high magnetocrystalline anisotropy (Kᵤ^{grain}) of 2.5×10⁷ erg/cm³ or more is exhibited when the content of SnO nonmagnetic material is 20 vol % or more and 45 vol % or less and a high magnetocrystalline anisotropy exceeding 2.6×10′ erg/cm³ is exhibited particularly when the content is 25 vol % or more and 45 vol % or less.

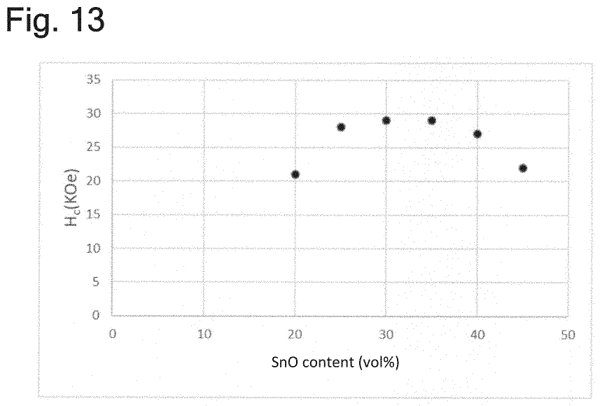

FIG. 13 reveals that the coercivity (H_{c}) is maximum when the content of SnO nonmagnetic material is 30 vol % and 35 vol % and that a high coercivity exceeding 25 kOe is exhibited when the content of SnO nonmagnetic material is 25 vol % or more and 40 vol % or less.

As in the foregoing, it is confirmed that all the saturation magnetization (Mₛ^{grain}), magnetocrystalline anisotropy (Kᵤ^{grain}), and _{coerc}iᵥit_{y} (H_{c}) are high when the content of SnO nonmagnetic material is 25 vol % or more and 40 vol % or less.

It is considered that a heat-assisted magnetic recording medium having the above-described magnetic characteristics and structure increases the signal due to its high saturation magnetization (Mₛ^{grain}) and thᵤₛ imₚroves SNR (signal-to-noise ratio). Further, the high uniaxial magnetic anisotropy is considered to increase the magnetic energy of such a heat-assisted magnetic recording medium, thereby improving the thermal stability.

1. A sputtering target for a heat-assisted magnetic recording medium, wherein the sputtering target comprises an FePt alloy, a nonmagnetic material, and incidental impurities, wherein the nonmagnetic material is an oxide having a melting point of 800° C. or higher and 1100° C. or lower.

2. The sputtering target for a heat-assisted magnetic recording

1. according to claim 1, wherein the sputtering target further comprises one or more elements selected from Ag, Au, and Cu.

3. The sputtering target for a heat-assisted magnetic recording medium according to claim 1, wherein the nonmagnetic material is one or more oxides selected from SnO, PbO, and Bi₂O₃.

4. The sputtering target for a heat-assisted magnetic recording medium according to claim 1, comprising, relative to the sputtering target for a heat-assisted magnetic recording medium, 25 vol % or more and 40 vol % or less of the nonmagnetic material.

5. The sputtering target for a heat-assisted magnetic recording medium according to claim 2, wherein the nonmagnetic material is one or more oxides selected from SnO, PbO, and Bi₂O₃.

6. The sputtering target for a heat-assisted magnetic recording medium according to claim 2, comprising, relative to the sputtering target for a heat-assisted magnetic recording medium, 25 vol % or more and 40 vol % or less of the nonmagnetic material.

7. The sputtering target for a heat-assisted magnetic recording medium according to claim 3, comprising, relative to the sputtering target for a heat-assisted magnetic recording medium, 25 vol % or more and 40 vol % or less of the nonmagnetic material.
